(19) United States
(12) Patent Application Publication
(10) Pub. No.: US 2025/0294687 A1
(43) Pub. Date: Sep. 18, 2025

(54) CHEMICAL SHIELDING STRUCTURE FOR IMMERSION COOLING

(71) Applicant: Micron Technology, Inc., Boise, ID (US)

(72) Inventors: Chen Yu Huang, Taichung City (TW); Chong Leong Gan, Taichung City (TW)

(21) Appl. No.: 19/076,326

(22) Filed: Mar. 11, 2025

Related U.S. Application Data
(60) Provisional application No. 63/564,256, filed on Mar. 12, 2024.

(51) Int. Cl. H05K 3/28; H05K 7/20

(52) U.S. Cl. CPC H05K 3/28; H05K 7/20236; H05K 7/20772

(57) ABSTRACT

A memory device for use in immersion cooling comprises a printed circuit board, one or more surface-mounted devices coupled to the printed circuit board, and an electrically non-conductive and thermally-conductive container surrounding the surface-mounted devices. The container may comprise a polymer bag or a Graphene-Reinforced Polymer enclosure. The polymer bag may be a polydimethylsiloxane film bag including a ceramic filler. The container is sealed to the printed circuit board at one or more sides of the printed circuit board, for example next to an M.2 connector.

### PRIORITY APPLICATION

This application claims the benefit of priority to U.S. Provisional Application Ser. No. 63/564,256, filed Mar. 12, 2024, which is incorporated herein by reference in its entirety.

### BACKGROUND

Immersion cooling is a method of cooling servers and other high-performance computing equipment. This technique involves submerging computer components or entire servers in a thermally conductive, but electrically insulating, liquid coolant. Unlike traditional air cooling or liquid cooling systems that use water blocks and radiators, immersion cooling directly exposes the components to the liquid, which has superior heat-absorbing properties.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

### BRIEF DESCRIPTION OF THE DRAWINGS

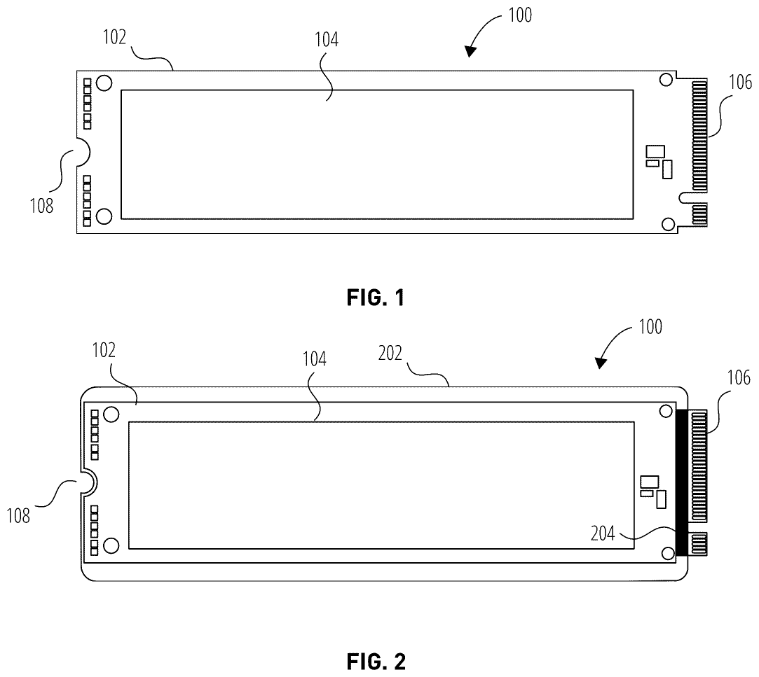

FIG. 1 is a plan view of a memory device including a PCB and one or more SMT devices, according to some examples.

FIG. 2 is a plan view of the memory device of FIG. 1 including a container in the form of a film bag, according to some examples.

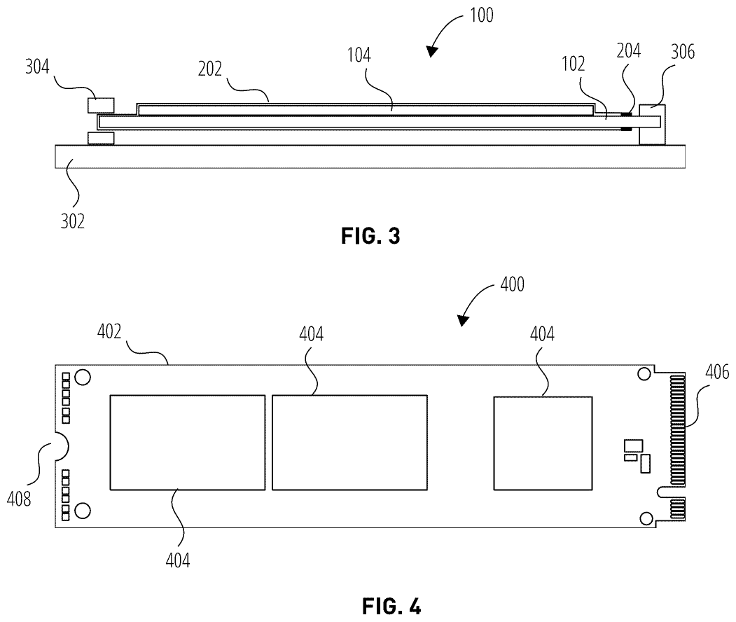

FIG. 3 is a side view of the memory device, including the film bag, of FIG. 2, according to some examples.

FIG. 4 is a plan view of a memory device including a PCB, according to some examples.

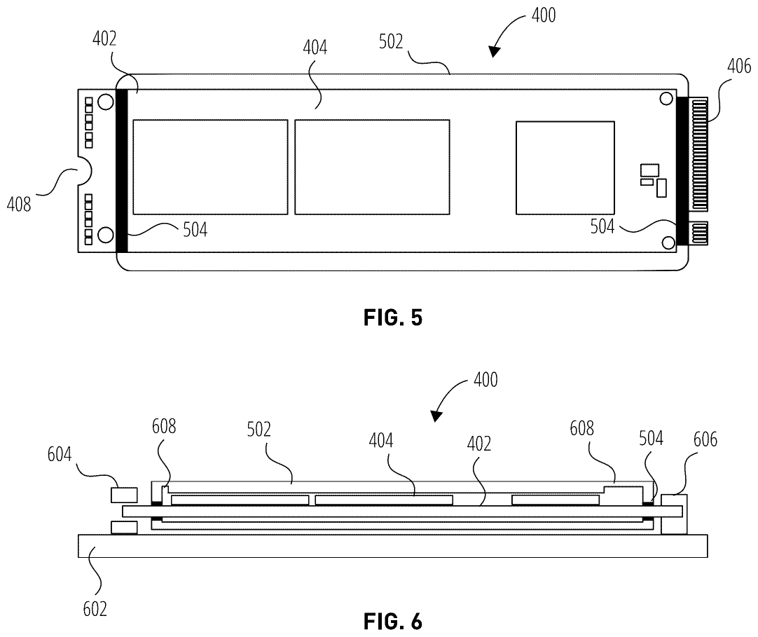

FIG. 5 is a plan view of a memory device including a container in the form of an enclosure, according to some examples.

FIG. 6 is a side view of the memory device, including the enclosure of FIG. 5, according to some examples.

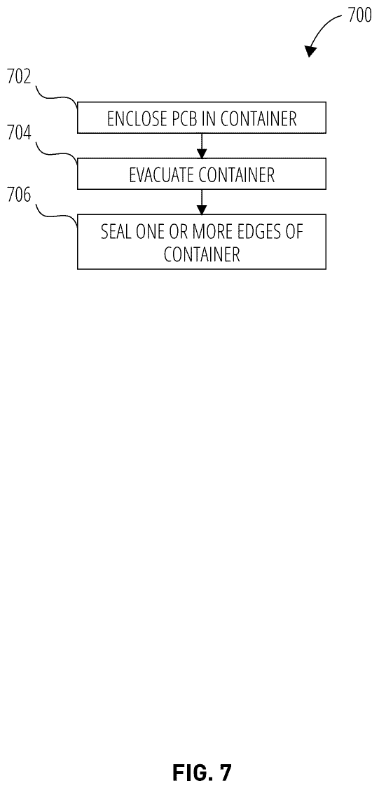

FIG. 7 is a flowchart describing a method of making a memory device, according to some examples.

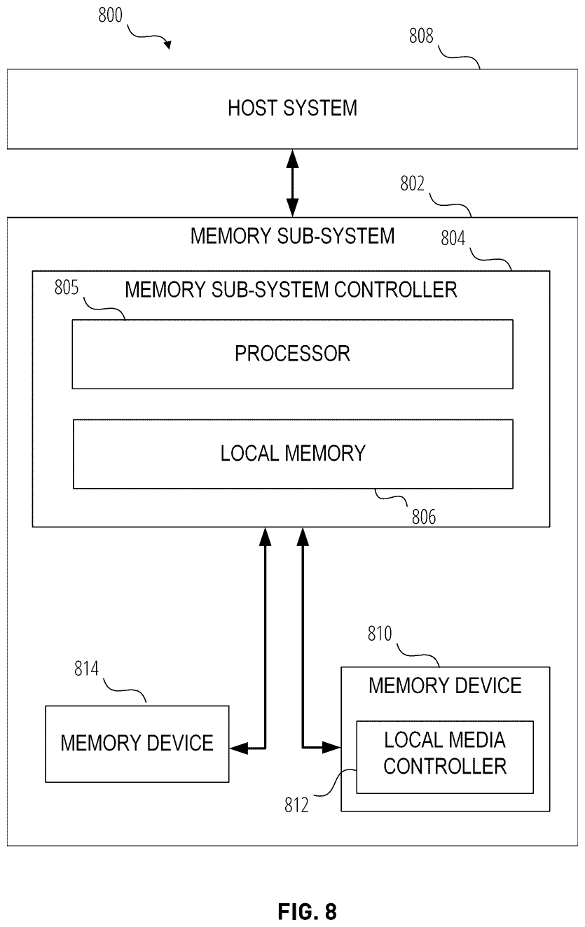

FIG. 8 is a block diagram illustrating a memory sub-system that can be implemented, at least in part, by an example memory device, in accordance with some examples.

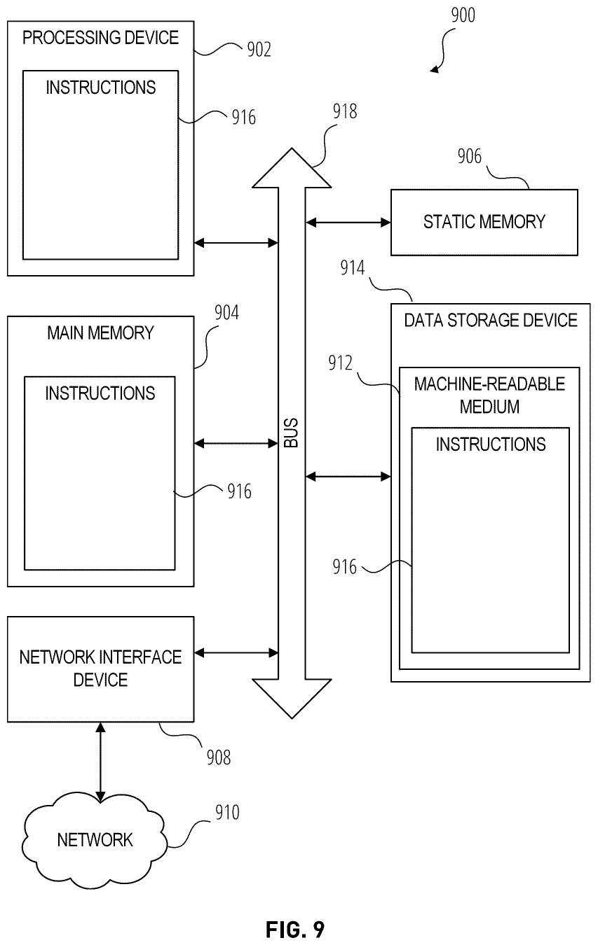

FIG. 9 illustrates a machine in the form of a computer system that can be implemented, at least in part, by a memory device, in accordance with some examples.

### DETAILED DESCRIPTION

Servers or components to be cooled by immersion cooling are placed inside a specially designed tank or container. This tank is then filled with a dielectric coolant, which is non-conductive and will not cause short circuits or electrical damage to the components. As the server components operate and generate heat, the heat is directly transferred to the surrounding liquid. The liquid has a much higher capacity to absorb and transfer heat compared to air, making it an efficient cooling medium.

The heated liquid naturally rises and is replaced by cooler liquid in a convection cycle, or it is actively pumped through a heat exchanger. The heat exchanger removes the heat from the liquid, which is then recirculated back into the tank. The heat exchanger often transfers the absorbed heat to a secondary cooling system, which could be a water loop or an external cooling unit, where it is finally dissipated away from the computing equipment.

The benefits of immersion cooling include the ability to handle higher heat loads more efficiently than air cooling, making it suitable for high-density computing environments like data centers, reduced the energy consumption associated with air cooling, lower noise levels, and the potential of extending the lifespan of the hardware.

In single-phase immersion cooling, electronic components are submerged in a non-conductive liquid that remains in a liquid state throughout the cooling process. The liquid absorbs the heat generated by the components, and natural convection or pumps circulate the liquid to transfer the heat away from the components. The heated liquid is then cooled using a heat exchanger and recirculated back into the system.

Dual-phase immersion cooling also involves submerging components in a dielectric liquid. However, in this method, the liquid is chosen for its low boiling point, allowing it to boil when it comes into contact with the hot components. The phase change from liquid to vapor effectively absorbs a significant amount of heat. A condenser mechanism is provided above the liquid coolant level, such as a cooled surface or coil. This condenser is maintained at a lower temperature, often by running a secondary coolant or water through it. When the vapor comes into contact with the cooler surface of the condenser, it releases its latent heat and changes phase back into a liquid and drips or flows back into the immersion tank. This creates a closed-loop cooling cycle where the coolant continuously evaporates and condenses, effectively transferring heat away from the electronic components.

Coolants used for immersion cooling have high thermal conductivity, low viscosity, and high heat capacity. However, there are integrated circuit (IC) packaging materials that could corrode or otherwise be adversely affected by such coolants. Cases of metal corrosion or polymer degradation are possible, arising mainly from interactions of the packaging materials with chemical additives or impurities in the coolant.

Instead of attempting to provide anti-corrosion packaging materials for individual Surface-Mount Technology (SMT) devices, disclosed herein is a container for enclosing a printed circuit board and its SMT devices to isolate the PCB and devices from the coolant. In some examples the container is either (a) a deformable, high thermal conductive protective thin film, and (b) a high thermal conductivity and corrosion resistant polymer enclosure to isolate all of the devices on a printed circuit board (PCB) or other device substrate from the liquid coolant, while still providing convenient installation and good thermal dissipation.

FIG. 1 is a plan view of a memory device 100 including a PCB 102 and one or more SMT devices 104, according to some examples. The PCB 102 includes an M.2 connector 106 at one end thereof and a screw notch 108 at the other end thereof. The one or more SMT devices 104 are mounted on the PCB 102. As used herein, the term surface-mounted device refers to any digital or analog processing or memory device coupled to a printed surface board, whether by Surface Mount Technology, Through-Hole-Technology (THT), a mix of SMT and TMT, Chip-on-Board (COB), Flip Chip, Through-Silicon Via (TSV) technology, and so forth. In some examples, the SMT device 104 is a memory sub-system, such as the memory sub-system 802 described below with reference to FIG. 8, which may be implemented as a data center Solid-State Device (SSD) system. Datacenter SSD systems can have very high workloads, for example, when used for AI applications, creating a lot of heat.

The surface-mounted devices include conventional semiconductor device packaging, such as molded plastic packages, ceramic packages, Chip-On-Board packaging, and so forth. In some examples, the PCB 102 includes both data processors and memory devices. In some examples, the data processors and memory devices are included in a single semiconductor package as shown in FIG. 1, while in other examples the data processors and memory devices may be provided in separate semiconductor packages as shown in FIG. 4. As used herein, the SMT device thus refers to both a single semiconductor package including multiple processors and/or memory devices, as well as to a semiconductor package including a single processor or memory device.

FIG. 2 is a plan view of the memory device 100 of FIG. 1 including a container in the form of a film bag 202, according to some examples. The film bag 202 is sized and shaped to enclose the PCB 102 and the SMT device 104, with the exception of the M.2 connector 106, which protrudes from the film bag 202. The PCB 102 and any components mounted thereon are scaled into the film bag 202 by a seal 204 to seal an opening of the film bag 202 next to the M.2 connector 106. The seal 204 in some examples is formed using a thermal hardening glue.

As can be seen, the film bag 202 surrounds most of the printed circuit board around and underneath the SMT device 104 as well as the SMT device 104 itself, with the exception of the M.2 connector 106. The film bag 202 can also be provided as a sleeve that fits over the PCB 102 and has two seals 204, one at each end or opening, as illustrated by the enclosure 502 described with reference to FIG. 5 below. It will thus be appreciated that that film bag 202 could cover more or less of the PCB 102 as long as it also covers the one or more SMT devices 104 and at least part of the PCB 102 around the surface-mounted devices.

In some examples, the film bag 202 encloses all SMT devices located on a PCB, to isolate all of the SMT devices from the coolant liquid in the thank. In other examples, depending on the nature of the packaging, the film bag 202 does not enclose all of the SMT devices on a PCB, but encloses at least SMT devices containing processors.

Prior to or during sealing, the film bag 202 is evacuated using a vacuum line inserted into the film bag 202 at the seal 204.

In some examples, the film bag 202 is made from two sheets of or Polydimethylsiloxane (PDMS) film. PDMS is a silicon-based organic polymer known for its unique properties such as flexibility, optical clarity, and thermal stability. PDMS film is created by curing liquid PDMS prepolymer, which is a viscous liquid, in a mold or on a substrate. The curing process can be accelerated by heat and results in a solid elastomeric film. The thickness of the film can be controlled during the manufacturing process, allowing for a wide range of applications that require different film thicknesses.

Polymers are typically thermal insulators, and a filler is thus added to the prepolymer to improve thermal conductivity. In some examples, a ceramic filler, such as aluminum oxide (Al2O3), silicon nitride (Si3N4), aluminum nitride (AlN) or boron nitride (BN) is used. In some examples, the PDMS film forming the film bag 202 has a thickness of 0.1 to 0.2 mm and a filler content of greater than 70% by weight. The manufacturing of the PDMS sheets is done using known techniques.

FIG. 3 is a side view of the memory device 100 including the film bag 202 of FIG. 2, according to some examples. The PCB 102 is shown mounted to a motherboard or backplane 302 with the M.2 connector 106 inserted into an M.2 socket 306 and held down by a screw 304 that fits into the screw notch 108 and engages the edge of the PCB 102. As can be seen, the evacuated film bag 202 confirms to the surface of the PCB and the SMT device 104, to provide improved thermal transfer from the SMT device 104 to the coolant liquid when mounted in the tank.

FIG. 4 is a plan view of a memory device 400 including a PCB 402, according to some examples. As before, the PCB 402 includes an M.2 connector 406 at one end thereof and a screw notch 408 at the other end thereof. One or more SMT devices 404 are mounted on the PCB 402.

FIG. 5 is a plan view of a memory device 400 including a container in the form of an enclosure 502, according to some examples. The enclosure 502 is sized and shaped to enclose the PCB 402 and the SMT devices 404, with the exception of the ends of the PCB 402, which protrude from the enclosure 502. The PCB 402 and any components mounted thereon are sealed into the enclosure 502 by two seals 204 to seal openings of the enclosure 502 at each end of the PCB 402. The seals 204 in some examples are formed using a thermal hardening glue. Prior to or during sealing, the enclosure 502 is evacuated using a vacuum line inserted into the enclosure 502 at the seal 504 adjacent to the M.2 connector 406.

As can be seen, the enclosure 502 surrounds most of the printed circuit board around and underneath the SMT devices 404 as well as the SMT devices 404 themselves, with the exception of the M.2 connector 406 and the screw notch 408. It will thus be appreciated that that the enclosure 502 could cover more or less of the PCB 402 as long as it also covers the one or more SMT devices 404 and at least part of the PCB 402 around the surface-mounted devices.

In some examples, the enclosure 502 is made of Graphene-Reinforced Polymer (GRP). GRP is a composite material where graphene is incorporated into a polymer matrix to enhance its properties. When the characteristics are of graphene are combined with a polymer substrate, the resulting composite material can exhibit improved performance in various aspects. In the current application, in addition to providing increased tensile strength and stiffness, the high thermal conductivity of graphene can improve the heat dissipation properties of the polymer, which is beneficial for immersion cooling of the PCB 402 and its SMT devices 404, as well as increased chemical resistance and barrier properties by providing a barrier to gases and chemicals, increasing the chemical resistance of the polymer.

The manufacturing of a GRP enclosure 502 is also compatible with existing manufacturing processes (ex: injection molding or extrusion of thermoplastics), which means that there is no need to make major changes to the current production lines of SMT device and PCB assembly manufacturers. The use of GRP as an additive also increases productivity and causes less tool wear, due to graphene contributing to better thermal conductivity and being a gentler additive compared to others.

In some examples, the polymer enclosure thickness from about 0.5-5 mm thick and the volume fraction of graphene filler is greater than or equal to 30% filler. The form of the graphene additive used for the enclosure 502 can vary depending on the manufacturing process and the desired properties of the final composite material, and include powder, flakes, sheets, nanoplatelets, nanoribbons. In some examples, derivatives of graphene that include various oxygen functional groups can be used, such as graphene oxide (GO) or reduced graphene oxide (rGO). The chosen form of graphene form is influenced by factors such as the desired distribution and orientation (if any) within the polymer and the processing technique (e.g., melt mixing, in-situ polymerization, or solution blending)

The polymer used, the chosen form of the graphene additive and the volume fraction is selected to achieve a balance of increased thermal conductivity without compromising the mechanical properties and processability of the GRP, and without incurring excessive cost.

FIG. 6 is a side view of the memory device 400, including the enclosure 502 of FIG. 5, according to some examples. As can be seen, the enclosure 502 encloses the PCB 402 and the SMT devices 404, with the exception of the ends of the PCB 402, which protrude from the enclosure 502. Also visible are the two seals 204 provided at each end of the PCB 402. The PCB 402 is mounted to a backplane 602 using a screw 604 positioned in the screw notch 408 after the M.2 connector 406 is inserted into an M.2 socket 606.

In some examples, the thickness of the enclosure 502 can vary along its length or width, to provide improved contact with the SMT devices 404 with thinner areas 608 around one or all of the SMTs to provide flexibility or reduced material usage. Additionally, while the enclosure 502 is illustrated as a sleeve that fits over the PCB 402 and has two seals 504, one at each end, in other examples the enclosure 502 can be provided as illustrated by the film bag 202, with a seal 204 at one end thereof with reference to FIG. 2 above.

FIG. 7 is a flowchart 700 describing a method of making a memory device according to some examples. The memory device in some examples is either the memory device 100 including film bag 202 or memory device 400 including enclosure 502 having the characteristics described above.

Although shown in a particular sequence or order, unless otherwise specified, the order of the operations can be modified. Thus, the illustrated examples should be understood only as examples, and the illustrated method can be performed in a different order, and some operations can be performed in parallel. Additionally, one or more operations can be omitted in various examples. Thus, not all operations are used in every example. Other process flows are possible.

The flowchart 700 commences at operation 702 with the PCB 102 or PCB 402 being enclosed by the film bag 202 or the enclosure 502, respectively. In operation 704, the film bag 202 or the enclosure 502 is evacuated. In operation 706, the film bag 202 is sealed at the seal 204 or the enclosure 502 is sealed at one or more seals 504, in some examples using thermal glue.

The memory devices 100, 400 can then be assembled to a backplane 302, 602 or into a larger computing device that is to be placed in an immersion tank for operation and cooling.

In view of the disclosure above, various examples are set forth below. It should be noted that one or more features of an example, taken in isolation or combination, should be considered within the disclosure of this application.
Example 1 is a memory device comprising: a printed circuit board; a plurality of memory components of a memory sub-system, the memory components being mounted on the printed circuit board; one or more processing devices mounted to the printed circuit board, the one or more processing devices being coupled to the memory components; and an electrically non-conductive and thermally-conductive container surrounding the one or more processing devices and at least part of the printed circuit board around the one or more processing devices, the container being configured to provide thermal conduction from the one or more processing devices to a fluid in an immersion tank.
In Example 2, the subject matter of Example 1 includes, wherein the container comprises a polymer bag.
In Example 3, the subject matter of Example 2 includes, wherein the printed circuit board comprises a connector located on a side thereof and the polymer bag has an opening that is sealed to the printed circuit board adjacent to the connector.
In Example 4, the subject matter of Examples 2-3 includes, wherein the polymer bag includes a ceramic filler to increase thermal conductivity.
In Example 5, the subject matter of Examples 2-4 includes, wherein the polymer bag is a polydimethylsiloxane (PDMS) film bag.
In Example 6, the subject matter of Example 5 includes, wherein the polymer bag includes a ceramic filler to increase thermal conductivity.
In Example 7, the subject matter of Example 6 includes, wherein the ceramic filler is selected from the group consisting of aluminum oxide, silicon nitride, aluminum nitride, and boron nitride.
In Example 8, the subject matter of Examples 6-7 includes, % or more by weight of the polymer bag.
In Example 9, the subject matter of Examples 1-8 includes, wherein the container comprises a Graphene-Reinforced Polymer (GRP) enclosure.
In Example 10, the subject matter of Example 9 includes, wherein the printed circuit board comprises a connector located on a side thereof and the GRP enclosure has an opening that is sealed to the printed circuit board adjacent to the connector.
In Example 11, the subject matter of Examples 9-10 includes, wherein the GRP enclosure includes a graphene additive selected from the group consisting of graphene flakes or graphene powder.
In Example 12, the subject matter of Examples 9-11 includes, wherein the GRP enclosure includes a graphene additive comprising a graphene oxide functional group.
In Example 13, the subject matter of Examples 9-12 includes, wherein the GRP enclosure comprises a sleeve that is sealed to the printed circuit board at opposite ends of the GRP enclosure.
In Example 14, the subject matter of Examples 9-13 includes, wherein the memory device comprises a data center solid-state device.
Example 15 is a method of making a memory device including a printed circuit board, a plurality of memory components of a memory sub-system, the memory components being mounted on the printed circuit board, one or more processing devices mounted to the printed circuit board, the one or more processing devices being coupled to the memory components, the method comprising: enclosing the printed circuit board and the one or more processing devices in an electrically non-conductive and thermally-conductive container surrounding the one or more processing devices and at least part of the printed circuit board around the one or more processing devices, the container being configured to provide thermal conduction from the one or more processing devices to a fluid in an immersion tank; and sealing an opening of the container to the printed circuit board.
In Example 16, the subject matter of Example 15 includes, evacuating the container at or before sealing an opening of the container to the printed circuit board.
In Example 17, the subject matter of Examples 15-16 includes, wherein the printed circuit board comprises a connector located on a side thereof and the sealed opening of the container is located adjacent to the connector.
In Example 18, the subject matter of Examples 15-17 includes, wherein the container is a is a polydimethylsiloxane (PDMS) film bag.
In Example 19, the subject matter of Example 18 includes, wherein the PDMS bag includes a ceramic filler to increase thermal conductivity.
In Example 20, the subject matter of Examples 15-19 includes, wherein the container comprises a Graphene-Reinforced Polymer (GRP) enclosure.
In Example 21, the subject matter of Example 20 includes, wherein the GRP enclosure includes a graphene additive selected from the group consisting of graphene flakes, graphene powder and a graphene oxide functional group.
In Example 22, the subject matter of Examples 20-21 includes, wherein the memory device comprises a data center solid-state device.
Example 23 is at least one machine-readable medium including instructions that, when executed by processing circuitry, cause the processing circuitry to perform operations to implement of any of Examples 1-22. Example 24 is an apparatus comprising means to implement of any of Examples 1-22. Example 25 is a system to implement of any of Examples 1-22. Example 26 is a method to implement of any of Examples 1-22.

FIG. 8 is a block diagram illustrating a memory sub-system 802 that can be implemented, at least in part, by a memory device 100, 400, in accordance with some examples. The memory sub-system 802 can include media, such as one or more volatile memory devices (e.g., memory device 814), one or more non-volatile memory devices (e.g., memory device 810), or a combination of such. A printed circuit board of an example can implement one or more of the memory device 810, the memory device 814, a memory sub-system controller 804, or the memory sub-system 802.

A memory sub-system 802 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

Computing environment 800 includes a host system 808 that is coupled to one or more memory sub-systems 802. In some examples, the host system 808 is coupled to different types of memory sub-system 802. FIG. 8 illustrates one example of a host system 808 coupled to one memory sub-system 802. The host system 808 uses the memory sub-system 802, for example, to write data to the memory sub-system 802 and read data from the memory sub-system 802. As used herein, “coupled to” generally refers to a connection between components, which can be an indirect communicative connection or direct communicative connection (e.g., without intervening components), whether wired or wireless, including connections such as electrical, optical, magnetic, etc.

The host system 808 can be a computing device such as a desktop computer, laptop computer, video game console, network server, mobile device, embedded computer (e.g., one included in a vehicle, industrial equipment, or a networked commercial device), or such computing device that includes a memory and a processing device. The host system 808 can be coupled to the memory sub-system 802 via a physical host interface. Examples of a physical host interface include, but are not limited to, a serial advanced technology attachment (SATA) interface, a peripheral component interconnect express (PCIe) interface, universal serial bus (USB) interface, Fiber Channel, Serial Attached SCSI (SAS), etc. The physical host interface can be used to transmit data between the host system 808 and the memory sub-system 802. The host system 808 can further utilize an NVM Express (NVMe) interface to access the memory components (e.g., memory devices 810) when the memory sub-system 802 is coupled with the host system 808 by the PCIe interface. The physical host interface can provide an interface for passing control, address, data, and other signals between the memory sub-system 802 and the host system 808.

The memory devices can include any combination of the different types of non-volatile memory devices and/or volatile memory devices. The volatile memory devices (e.g., memory device 814) can be, but are not limited to, random access memory (RAM), such as dynamic random access memory (DRAM) and synchronous dynamic random access memory (SDRAM).

An example of non-volatile memory devices (e.g., memory device 810) includes a negative-and (NAND) type flash memory. Each of the memory devices 810 can include one or more arrays of memory cells such as single-level cells (SLCs) or multi-level cells (MLCs) (e.g., triple-level cells (TLCs) or quad-level cells (QLCs)). In some examples, a particular memory component can include an SLC portion, and an MLC portion, a TLC portion, or a QLC portion of memory cells. Each of the memory cells can store one or more bits of data used by the host system 808. Furthermore, the memory cells of the memory devices 810 can be grouped as memory pages or memory blocks that can refer to a unit of the memory component used to store data.

Although non-volatile memory components such as NAND type flash memory are described, the memory device 810 can be based on any other type of non-volatile memory, such as read-only memory (ROM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

The memory sub-system controller 804 can communicate with the memory devices 810 to perform operations such as reading data, writing data, or erasing data at the memory devices 810 and other such operations. The memory sub-system controller 804 can include hardware such as one or more integrated circuits and/or discrete components, a buffer memory, or a combination thereof. The memory sub-system controller 804 can be a microcontroller, special purpose logic circuitry (e.g., a field programmable gate array (FPGA), an application specific integrated circuit (ASIC), etc.), or other suitable processor.

The memory sub-system controller 804 can include a processor (processing device) 805 configured to execute instructions stored in local memory 806. In the illustrated example, the local memory 806 of the memory sub-system controller 804 includes an embedded memory configured to store instructions for performing various processes, operations, logic flows, and routines that control operation of the memory sub-system 802, including handling communications between the memory sub-system 802 and the host system 808.

In some examples, the local memory 806 can include memory registers storing memory pointers, fetched data, etc. The local memory 806 can also include read-only memory (ROM) for storing micro-code. While the example memory sub-system 802 in FIG. 8 has been illustrated as including the memory sub-system controller 804, in another example of the present disclosure, a memory sub-system 802 may not include a memory sub-system controller 804, and may instead rely upon external control (e.g., provided by an external host, or by a processor or controller separate from the memory sub-system).

In general, the memory sub-system controller 804 can receive commands or operations from the host system 808 and can convert the commands or operations into instructions or appropriate commands to achieve the desired access to the memory devices 810. The memory sub-system controller 804 can be responsible for other operations such as wear leveling operations, garbage collection operations, error detection and error-correcting code (ECC) operations, encryption operations, caching operations, and address translations between a logical block address and a physical block address that are associated with the memory devices 810. The memory sub-system controller 804 can further include host interface circuitry to communicate with the host system 808 via the physical host interface. The host interface circuitry can convert the commands received from the host system into command instructions to access the memory devices 810 as well as convert responses associated with the memory devices 810 into information for the host system 808.

The memory sub-system 802 can also include additional circuitry or components that are not illustrated. In some examples, the memory sub-system 802 can include a cache or buffer (e.g., DRAM) and address circuitry (e.g., a row decoder and a column decoder) that can receive an address from the memory sub-system controller 804 and decode the address to access the memory devices 810.

In some examples, the memory devices 810 include local media controllers 812 that operate in conjunction with memory sub-system controller 804 to execute operations on one or more memory cells of the memory devices 810.

FIG. 9 illustrates a machine in the form of a computer system 900 that can be implemented, at least in part, by a memory device, in accordance with some examples. In some examples, the computer system 900 can correspond to a host system (e.g., the host system 808 of FIG. 8) that includes, is coupled to, or utilizes a memory sub-system (e.g., the memory sub-system 802 of FIG. 5) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a Mini PC, a laptop, a video game console, a set-top box (STB), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a data storage device 914, which communicate with each other via a bus 918.

The processing device 902 represents one or more general-purpose processing devices such as a microprocessor, a central processing unit, or the like. More particularly, the processing device 902 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 902 can also be one or more special-purpose processing devices such as an application specific integrated circuit (ASIC), a field programmable gate array (FPGA), a digital signal processor (DSP), a network processor, or the like. The processing device 902 is configured to execute instructions 916 for performing the operations and steps discussed herein. The computer system 900 can further include a network interface device 908 to communicate over a network 910.

The data storage device 914 can include a machine-readable storage medium 912 (also known as a computer-readable medium) on which is stored one or more sets of instructions 916 or software embodying any one or more of the methodologies or functions described herein. The instructions 916 can also reside, completely or at least partially, within the main memory 904 and/or within the processing device 902 during execution thereof by the computer system 900, the main memory 904 and the processing device 902 also constituting machine-readable storage media. The machine-readable storage medium 912, data storage device 914, and/or main memory 904 can correspond to the memory sub-system 802 of FIG. 8.

In one example, the instructions 916 include instructions to implement functionality as described above. While the machine-readable storage medium 912 is shown, in some examples, to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

The foregoing disclosure describes specific example implementations. It will be evident that various modifications can be made thereto without departing from the broader spirit and scope of examples of the disclosure as set forth in the following claims. The specification and drawings are, accordingly, to be regarded in an illustrative sense rather than a restrictive sense.

What is claimed is:

1. A memory device comprising:
a printed circuit board;
a plurality of memory components of a memory sub-system, the memory components being mounted on the printed circuit board;
one or more processing devices mounted to the printed circuit board, the one or more processing devices being coupled to the memory components; and
an electrically non-conductive and thermally-conductive container surrounding the one or more processing devices and at least part of the printed circuit board around the one or more processing devices, the container being configured to provide thermal conduction from the one or more processing devices to a fluid in an immersion tank.

2. The memory device of claim 1, wherein the container comprises a polymer bag.

3. The memory device of claim 2, wherein the printed circuit board comprises a connector located on a side thereof and the polymer bag has an opening that is sealed to the printed circuit board adjacent to the connector.

4. The memory device of claim 2, wherein the polymer bag includes a ceramic filler to increase thermal conductivity.

5. The memory device of claim 2, wherein the polymer bag is a polydimethylsiloxane (PDMS) film bag.

6. The memory device of claim 5, wherein the polymer bag includes a ceramic filler to increase thermal conductivity.

7. The memory device of claim 6, wherein the ceramic filler is selected from the group consisting of aluminum oxide, silicon nitride, aluminum nitride, and boron nitride.

8. The memory device of claim 6, wherein the ceramic filler is 70% or more by weight of the polymer bag.

9. The memory device of claim 1, wherein the container comprises a Graphene-Reinforced Polymer (GRP) enclosure.

10. The memory device of claim 9, wherein the printed circuit board comprises a connector located on a side thereof and the GRP enclosure has an opening that is sealed to the printed circuit board adjacent to the connector.

11. The memory device of claim 9, wherein the GRP enclosure includes a graphene additive selected from the group consisting of graphene flakes or graphene powder.

12. The memory device of claim 9, wherein the GRP enclosure includes a graphene additive comprising a graphene oxide functional group.

13. The memory device of claim 9, wherein the GRP enclosure comprises a sleeve that is sealed to the printed circuit board at opposite ends of the GRP enclosure.

14. The memory device of claim 9, wherein the memory device comprises a data center solid-state device.

15. A method of making a memory device including a printed circuit board, a plurality of memory components of a memory sub-system, the memory components being mounted on the printed circuit board, one or more processing devices mounted to the printed circuit board, the one or more processing devices being coupled to the memory components, the method comprising:
enclosing the printed circuit board and the one or more processing devices in an electrically non-conductive and thermally-conductive container surrounding the one or more processing devices and at least part of the printed circuit board around the one or more processing devices, the container being configured to provide thermal conduction from the one or more processing devices to a fluid in an immersion tank; and
sealing an opening of the container to the printed circuit board.

16. The method of claim 15, further comprising:
evacuating the container at or before sealing an opening of the container to the printed circuit board.

17. The method of claim 15, wherein the printed circuit board comprises a connector located on a side thereof and the sealed opening of the container is located adjacent to the connector.

18. The method of claim 15, wherein the container is a is a polydimethylsiloxane (PDMS) film bag.

19. The method of claim 18, wherein the PDMS bag includes a ceramic filler to increase thermal conductivity.

20. The method of claim 15, wherein the container comprises a Graphene-Reinforced Polymer (GRP) enclosure.
